(19) United States
(12) Patent Application Publication
(10) Pub. No.: US 2026/0010678 A1
(43) Pub. Date: Jan. 8, 2026

(54) CONSTRAINED GENERATION FOR ACCELERATED MATERIAL DISCOVERY AND DESIGN USING GENERATIVE ARTIFICIAL INTELLIGENCE MODELS

(71) Applicant: International Business Machines Corporation, Armonk, NY (US)

(72) Inventors: Nathaniel H. PARK, San Jose, CA (US); James L. HEDRICK, Pleasanton, CA (US); Sarathkrishna SWAMINATHAN, Santa Clara, CA (US); Brandi RANSOM, San Jose, CA (US)

(21) Appl. No.: 18/762,235

(22) Filed: Jul. 2, 2024

(51) Int. Cl. G06F 30/27; G06F 30/17

(52) U.S. Cl. CPC G06F 30/27; G06F 30/17

(57) ABSTRACT

Disclosed embodiments provide methods, systems, and computer program products for implementing constrained generation for material discovery and material design using generative artificial intelligence (AI) foundation models. A disclosed non-limiting method includes providing, using one or more processors, a chemical structure at a user design interface; receiving, at a foundation model, a user selection of a portion of the chemical structure and a user-input prompt for replacing the portion, where the user-input prompt indicates a desired property of a replacement portion; and generating, by the foundation model, the replacement portion, where the replacement portion replaces the selected portion of the chemical structure and includes a generated chemical structure predicted to have the desired property.

### BACKGROUND

The present invention relates to digital processing systems, and more specifically, to efficiently implementing constrained generation for materials discovery and material design using generative artificial intelligence (AI).

A need exists for generative AI systems to effectively generate useful new materials, and material designs, that can enable efficiently identifying specific new materials and material designs of interest for experimental validation. A need exists for new systems and techniques to enable efficient and effective constrained generation for materials discovery and design using generative AI.

### SUMMARY

Disclosed embodiments provide methods, systems, and computer program products for implementing constrained generation for material discovery and material design using generative artificial intelligence (AI) foundation models.

According to one embodiment of the present disclosure, a non-limiting method comprises providing, using one or more processors, a chemical structure at a design interface. A user selection of a portion of the chemical structure and a user-input prompt for replacing the portion are received at a foundation model, where the user-input prompt indicates a desired property of a replacement portion. The foundation model generates the replacement portion, where the replacement portion replaces the selected portion of the chemical structure and includes a generated chemical structure predicted to have the desired property.

An aspect of a non-limiting method of one disclosed embodiment includes receiving user feedback based on the generated chemical structure. The foundation model is tuned based on the user input selection, the user-input prompt, the generated chemical structure, and the user feedback.

An aspect of a non-limiting method of one disclosed embodiment includes receiving, by retrieval augmented generation (RAG) of the foundation model, historical data of one or more of prior user modifications or user-input constraints to one or more pre-generated datasets of chemical compounds, spectra, or similar data. The historical data are shared in response to a natural language user selection or user interaction.

According to one embodiment of the present disclosure, a system comprises one or more computer processors; and a memory containing a program which when executed by the one or more computer processors performs an operation, the operation comprises providing, using one or more processors, a chemical structure at a design interface. A user selection of a portion of the chemical structure and a user-input prompt for replacing the portion are received at a foundation model, where the user-input prompt indicates a desired property of a replacement portion. The foundation model generates the replacement portion, where the replacement portion replaces the selected portion of the chemical structure and includes a generated chemical structure predicted to have the desired property.

According to one embodiment of the present disclosure, a computer program product comprises a computer-readable storage medium having computer-readable program code embodied therewith, the computer-readable program code executable by one or more computer processors to perform an operation comprises providing, using one or more processors, a chemical structure at a design interface. A user selection of a portion of the chemical structure and a user-input prompt for replacing the portion are received at a foundation model, where the user-input prompt indicates a desired property of a replacement portion. The foundation model generates the replacement portion, where the replacement portion replaces the selected portion of the chemical structure and includes a generated chemical structure predicted to have the desired property.

### BRIEF DESCRIPTION OF THE DRAWINGS

FIG. 1 is a block diagram of an example computer environment for use in conjunction with one or more disclosed embodiments;

FIG. 2 is a schematic and block diagram illustrating an example system for implementing constrained generation for materials discovery and design of one or more embodiments of the present disclosure;

FIGS. 3A, and 3B together provide a flow chart illustrating example operations of a method of constrained generation for materials discovery and design of one or more disclosed embodiments;

FIG. 4 is a diagram illustrating example operations, design interface features, and results of a constrained generation method including an illustrated Perfluoroalkyl and polyfluoroalkyl substances (PFAS) molecule for materials discovery and design of one or more disclosed embodiments;

FIG. 5 is a diagram illustrating example operations, design interface features, and results of a constrained generation method including multiple example organic compounds for materials discovery and design of one or more disclosed embodiments;

FIG. 6 is a diagram illustrating example operations, design interface features, and results of an in-context learning method for constraint generation used with Simplified Molecular Input Line Entry System (SMILES) strings for materials discovery and design of one or more disclosed embodiments;

FIG. 7 is a diagram illustrating example operations, design interface features, and results of a method of constrained generation of example polymer and polymeric materials for materials discovery and design of one or more disclosed embodiments;

FIG. 8 is a diagram illustrating example operations, design interface features, and results of a constrained generation method of an example inorganic material for materials discovery and design of one or more disclosed embodiments;

FIG. 9 is a diagram illustrating example operations, design interface features, and results of a constrained generation method including multiple example inorganic materials for materials discovery and design of one or more disclosed embodiments;

FIG. 10 is a diagram illustrating example operations, design interface features, and results of a constrained generation method including example interaction with characterization data processing for materials discovery and design of one or more disclosed embodiments;

FIG. 11 is a diagram illustrating example operations, design interface features, and results of a constrained generation method of an example inverse design and structural constraints for materials discovery and design of one or more disclosed embodiments; and

FIG. 12 is a flowchart illustrating example features and operations of a method for implementing constrained generation for materials discovery and design of a disclosed embodiment.

### DETAILED DESCRIPTION

Embodiments herein describe systems and techniques enabling effective use of generative AI foundation models for new material discovery and material design. Disclosed embodiments enable user selection of a portion of the chemical structure to be replaced and interactively apply constraints to identify and output new chemical compounds, materials, and material designs using foundation models and computer software tools. In this manner, the described techniques enable enhanced processing speed, reducing an overall computer system time used for implementing robust, effective, and efficient constrained generation for new chemical compounds, material discovery and material design using generative AI foundation models.

According to an aspect of disclosed embodiments, a non-limiting computer implemented method is provided. The method of a first embodiment 1 comprises providing, using one or more processors, a chemical structure at a design interface; receiving, at a foundation model, a user selection of a portion of the chemical structure and a user-input prompt for replacing the portion, where the user-input prompt indicates a desired property of a replacement portion; and generating, by the foundation model, the replacement portion, where the replacement portion replaces the selected portion of the chemical structure and includes a generated chemical structure predicted to have the desired property. The method of the first embodiment 1 enables user selection of a portion of the chemical structure and user-input prompt for replacing the portion, enabling effective and efficient use of the foundation model for materials discovery and design, to identify promising new material designs.

According to an aspect of disclosed embodiments, a non-limiting computer implemented method of an embodiment 2 comprises providing, using one or more processors, a chemical structure at a design interface; receiving, at a foundation model, a user selection of a portion of the chemical structure and a user-input prompt for replacing the portion, where the user-input prompt indicates a desired property of a replacement portion; generating, by the foundation model, the replacement portion, where the replacement portion replaces the selected portion of the chemical structure and includes a generated chemical structure predicted to have the desired property; receiving user feedback based on the generated chemical structure; and tuning the foundation model based on one or more of the user selection, the user-input prompt, the generated chemical structure, and the user feedback. The method of embodiment 2 enables users to provide feedback based on the generated chemical structure and tuning the foundation model based on one or more of the user selection, the user-input prompt, the generated chemical structure, and the user feedback, which enables enhanced foundation models for materials discovery and design, to identify promising new material designs.

According to an aspect of disclosed embodiments, a non-limiting computer implemented method of an embodiment 3 comprises providing, using one or more processors, a chemical structure at a design interface; receiving, at a foundation model, a user selection of a portion of the chemical structure and a user-input prompt for replacing the portion, where the user-input prompt indicates a desired property of a replacement portion; generating, by the foundation model, the replacement portion that replaces the selected portion of the chemical structure and includes a generated chemical structure predicted to have the desired property; where receiving, at the foundation model, further comprises receiving, by retrieval augmented generation (RAG) of the foundation model, historical data of one or more of prior user modifications or user-input constraints to one or more pre-generated datasets of chemical compounds, spectra, or similar data, and sharing the historical data in response to a natural language user selection or user interaction. The method of embodiment 3 enables RAG of the foundation model and sharing the historical data in response to a natural language user selection or user interaction, which enables effective and efficient use of the foundation model for materials discovery and design to identify promising new material designs.

According to an aspect of disclosed embodiments, a system is provided. The system of the first embodiment 1 comprises one or more computer processors; and a memory containing a program which when executed by the one or more computer processors performs an operation, the operation comprises providing, using one or more processors, a chemical structure at a design interface; receiving, at a foundation model, a user selection of a portion of the chemical structure and a user-input prompt for replacing the portion, where the user-input prompt indicates a desired property of a replacement portion; and generating, by the foundation model, the replacement portion, where the replacement portion replaces the selected portion of the chemical structure and includes a generated chemical structure predicted to have the desired property. The system of the first embodiment 1 enables of the first embodiment 1 enables user selection of a portion of the chemical structure and user-input prompt for replacing the portion, enabling effective and efficient use of the foundation model for materials discovery and design, to identify promising new material designs.

According to an aspect of disclosed embodiments, a computer program product is provided. The computer program product of the first embodiment 1 comprises a computer-readable storage medium having computer-readable program code embodied therewith, the computer-readable program code executable by one or more computer processors to perform an operation comprises providing, using one or more processors, a chemical structure at a design interface; receiving, at a foundation model, a user selection of a portion of the chemical structure and a user-input prompt for replacing the portion, where the user-input prompt indicates a desired property of a replacement portion; and generating, by the foundation model, the replacement portion, where the replacement portion replaces the selected portion of the chemical structure and includes a generated chemical structure predicted to have the desired property. The computer program product of the first embodiment 1 enables user selection of a portion of the chemical structure and user-input prompt for replacing the portion, enabling effective and efficient use of the foundation model for materials discovery and design, to identify promising new material designs.

Additionally, the method of embodiments 1, 2, and 3 of the present disclosure further includes receiving, at the foundation model, user-input interactions and user-input constraints for modifying the replacement portion; and generating, by the foundation model, a modified chemical structure for the replacement portion based on one or more of the user-input interactions, and user-input constraints. This method enables user-input interactions and user-input constraints to modify the replacement portion, which bolsters the effective and efficient use of the foundation model for materials discovery and design, to speed up system processing and reduce both system and user time requirements, which depend on the choice of user-input interactions and user-input constraints.

Additionally, the method of embodiments 1, and 3 of the present disclosure further includes receiving user feedback based on the generated chemical structure; and tuning the foundation model based on one or more of the user input selection, the user-input prompt, the generated chemical structure, and the user feedback. This method of embodiments 1, and 3 enables users to provide feedback based on the generated chemical structure, and tuning the foundation model is performed based on one or more of the user selection, the user-input prompt, the generated chemical structure, and the user feedback, which enables enhanced foundation models for materials discovery and design, which depend on the user feedback.

Additionally, the method of embodiments 1, 2, and 3 of the present disclosure where the user-input prompt comprises at least one of natural language prompts, boundary conditions, a combination of natural language and explicit property settings. The method of embodiments 1, 2, and 3 enables users to effectively and efficiently input prompts to reduce both system and user time requirements for materials discovery and design, and enables enhanced use of the foundation model, which depend on the choice of the user-input prompt.

Additionally, the method of embodiments 1, 2 and 3 of the present disclosure where the user-input prompt comprises user-input property settings that indicates the desired property of the replacement portion, where the user-input property settings comprise one or more of a physical property, a chemical property, a thermal property, and a mechanical property. This method of embodiments 1, 2 and 3 enables users to effectively and efficiently input property settings that indicate the desired property of the replacement portion, enabling effective and efficient use of the foundation model for enhanced materials discovery and design, to speed up processing, reducing both system and user time requirements.

Additionally, the method of embodiments 1, 2 and 3 of the present disclosure further includes obtaining a user-input dataset of materials or compounds with a set of properties; and receiving, at a foundation model, a user selection of a region of the dataset and one or more user-input constraints for replacing the region, where the one or more user-input constraints indicate a desired property of a replacement region. This method of embodiments 1, 2 and 3 enables effective and efficient use of the foundation model for materials discovery and design utilizing a user-input dataset of materials or compounds with a set of properties, and enabling the user to efficiently provide a user selection of a region of the dataset and one or more user-input constraints for replacing the region.

Additionally, the method of embodiments 1, 2 and 3 of the present disclosure further includes receiving user-input structural constraints; and generating the replacement region that replaces the selected region of one or more materials or compounds that match one or more of the user selection, the one or more user-input constraints, and the user-input structural constraints. This method of embodiments 1, 2 and 3 enables effective and efficient use of the foundation model for materials discovery and design, enabling the user to efficiently provide user-input structural constraints that can be effectively and efficiently used to generate the replacement region.

Additionally, the method of embodiments 1, 2, and 3 of the present disclosure further includes tracking and encoding at least one of user selections, user-input interactions, and user-input constraints for ingestion into the foundation model for constrained generation of a modified chemical structure. This method of embodiments 1, 2 and 3 enables effective and efficient use of the foundation model for materials discovery and design, enabling fine tuning of the foundation model, and in-context learning that can be effectively used to generate the replacement region and that includes the generated chemical structure predicted to have the desired property.

Additionally, the method of embodiments 1, 2, and 3 of the present disclosure further includes generating visualizations of chemical, material, or property latent space of the generated chemical structure based on one or more of user defined constraints, selections, and interaction data. This method of embodiments 1, 2 and 3 enable effective and efficient use of the foundation model for materials discovery and design, enabling the user to effectively and efficiently generate and modify the replacement region and the generated chemical structure based on the generated visualizations of chemical, material, or property latent space of the generated chemical structure.

Additionally, the method of embodiments 1, 2, and 3 of the present disclosure further includes receiving, at the foundation model, one or more of user-input interaction data, user selection data, and user-input constraint data to generate a prompt based on in-context learning of the one or more of user-input interaction data, user selection data, and user-input constraint data to generate the replacement portion. This method of embodiments 1, 2 and 3 enables generating the prompt based on in-context learning of the one or more of user-input interaction data, user selection data, and user-input constraint data, which enhances the prompt to enable enhanced materials discovery and design.

Additionally, the method of embodiments 1, 2, and 3 of the present disclosure further includes receiving, at the foundation model, one or more of user-input interaction data, user selection data, or user-input constraint data; and performing fine-tuning of the foundation model based on the one or more of user-input interaction data, user selection data, and user-input constraint data. This method of embodiments 1, 2, and 3 enables improved processing speed for materials discovery and design based on the enhanced foundation model enabled by fine-tuning of the foundation model.

Additionally, the method of embodiments 1, 2 and 3 of the present disclosure further includes performing, by the foundation model, one or more of computational chemistry processing and simulation processing based on one or more of user-input selections, and user-input constraints to generate a modified chemical structure. This method of embodiments 1, 2, and 3 enables improved processing speed with computational chemistry processing or simulation processing by the foundation model, enabling the user to generate and modify the replacement region and include the generated chemical structure predicted to have the desired property with reduced user and system time for materials discovery and design.

Additionally, the method of embodiments 1, and 2 of the present disclosure further includes receiving, by retrieval augmented generation (RAG) of the foundation model, historical data of one or more of prior user modifications or user-input constraints to one or more pre-generated datasets of chemical compounds, spectra, or similar data, and sharing the historical data in response to a natural language user selection or user interaction. This method of embodiments 1, and 2 enables improved processing speed with the enhanced foundation model and sharing the historical data in response to a natural language user selection or user interaction by the user.

Additionally or alternatively, the method, system, and computer program product of embodiments 1, 2 and 3 in which generating, by the foundation model, the replacement portion, may further include receiving, at the foundation model, user-input interactions or user-input constraints for modifying the replacement portion of the generated chemical structure; and generating, by the foundation model, a modified chemical structure for the replacement portion based on one or more of the user-input interactions, and user-input constraints. Additionally, or alternatively, such combined embodiment may have the technical effect of and/or may be useful for improved system processing speed based on the user-input interactions or user-input constraints, enabling reduced user and system time for materials discovery and design.

Additionally or alternatively, the method, system, and computer program product of embodiment 1, 2, and 3 in which the generating, by the foundation model, the replacement portion, further comprises receiving user feedback based on the generated chemical structure; and tuning the foundation model based on one or more of the user input selection, the user-input prompt, the generated chemical structure, and the user feedback. Additionally, or alternatively, such combined embodiment may have the technical effect of and/or may be useful for improved system processing speed enabled by the enhanced foundation model, enabling reduced user and system time for materials discovery and design.

Additionally or alternatively, the method, system, and computer program product of embodiments 1, 2 and 3 in which the user-input prompt comprises at least one of natural language prompts, boundary conditions, and a combination of natural language and explicit property settings. Additionally or alternatively, such combined embodiment of the user-input prompt may have the technical effect of and/or may be useful for enabling users to effectively and efficiently indicate a desired property of a replacement portion based on at least one of natural language prompts, boundary conditions, and a combination of natural language and explicit property settings.

Additionally or alternatively, the method, system, and computer program product of embodiments 1, 2 and 3 in which the user-input prompt comprises user-input property settings that indicates the desired property of the replacement portion, where the user-input property settings comprise one or more of a physical property, a chemical property, a thermal property, and a mechanical property. Additionally or alternatively, such combined embodiment of the user-input property settings may have the technical effect of and/or may be useful to enable users to effectively and efficiently provide the desired property of the replacement portion, and reduce both system and user time for materials discovery and design, enabled by the foundation model.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

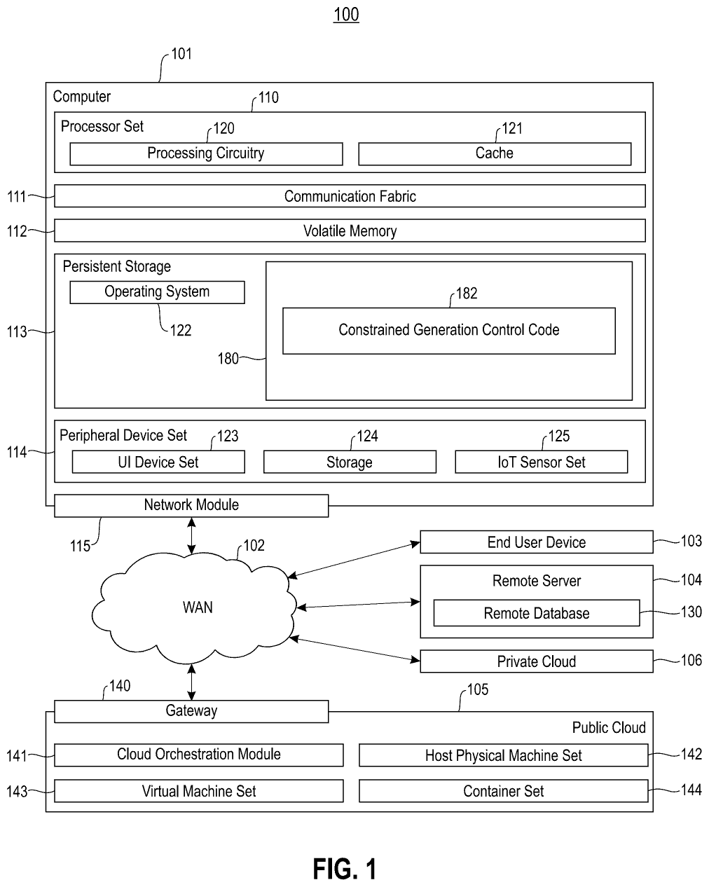

Referring to FIG. 1, a computing environment 100 contains an example of an environment for the execution of at least some of the computer code involved in performing the inventive methods, such as a Constrained Generation Control Code 182, at block 180. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

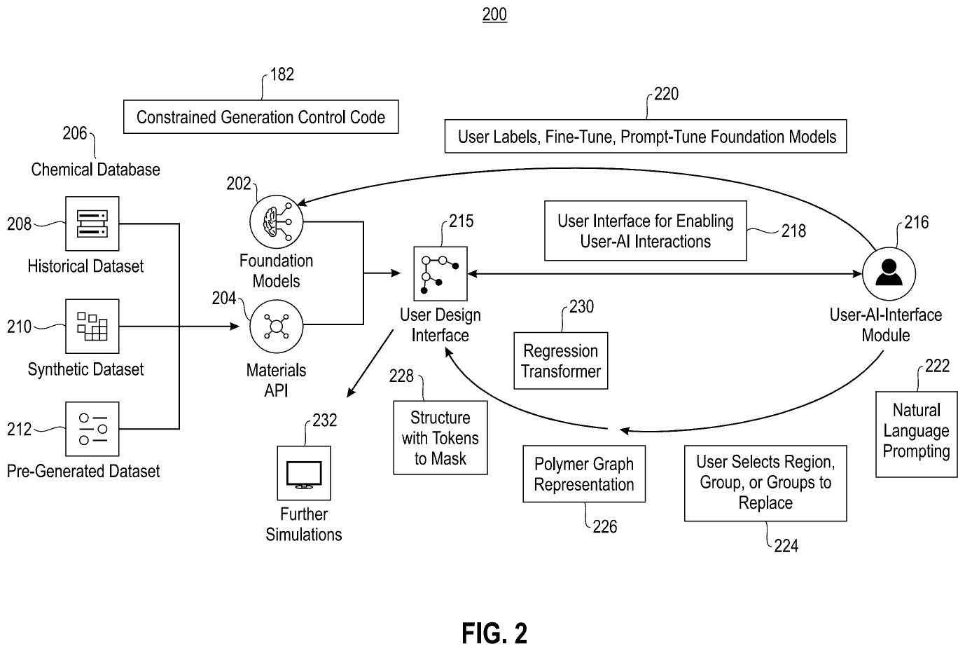

FIG. 2 is a schematic and block diagram illustrating an example system 200 for implementing constrained generation for new material discovery and material design of one or more embodiments of the present disclosure. System 200 can be used in conjunction with the computer 101 and cloud environment of the computing environment 100 of FIG. 1 with the Constrained Generation Control Code 182 to implement chemical compound, material discovery, and material design of disclosed embodiments. In a disclosed embodiment, system 200 enables robust, effective and efficient generation of chemical structures. System 200 provides a chemical structure at a user design interface 215 of disclosed embodiments and receives, at a foundation model 202, a user selection of a portion of the chemical structure to be replaced and a user-input prompt that indicates a desired property of a replacement portion of the chemical structure. In a disclosed embodiment, the foundation model 202 outputs a generated chemical structure that includes a replacement portion predicted to have the user-input desired property.

In an embodiment, system 200 includes one or more foundation models 202 of any suitable implementation. In an embodiment, system 200 includes foundation models 202 with a materials Application Program Interface (API) 204 coupled to a chemical database 206. The chemical database 206 of disclosed embodiments stores massive material or chemical information including chemical structures, chemical and physical properties, identifiers, constraints, user-input selections, user-input feedback, and the like. As shown, the chemical database 206 includes one or more of a historical dataset 208, synthetic dataset 210, and a pre-generated dataset 212 coupled to the foundation models 202 via the materials API 204.

System 200 includes the user design interface 215 coupled to the foundation models 202 and the materials API 204, which facilitates the human AI interaction and allows real time generation of new compounds and structures. System 200 includes a user-AI-interface module 216 coupled to the user design interface 215, which receives an input from a human, e.g., user or subject matter expert (SME). System 200 implements features and operations including tracking and encoding user selections and user-AI interactions, such as indicated by a functional block 218 labeled User Interface for Enabling user-AI Interactions at a line between the user design interface 215 and the user-AI-interface module 216. In an embodiment, the foundation models 202 present options for user-input via the user design interface 215 and the user-AI-interface module 216, receive manual inputs, and user interactions, such as user selections of fragments of chemical compounds, spectra, or similar data, such as a portion of a chemical structure, user-input natural language prompts, and explicit property settings for constrained generation of materials, compounds, and design output with predicted values of interest. The user design interface 215 presents one or more candidates or sets of one or more generated chemical structures output by the foundation models 202 to the user or SME, based on user selections and user-AI Interactions.

In an embodiment, system 200 implements features and operations including enabling user feedback of user selections or user labels, and user-AI-interaction data to fine-tune or prompt-tune generative AI foundations models for improved candidate generation of materials, compounds, and design output with predicted values of interest. System 200 enables enhanced material discovery and design for improved candidate generation, such as indicated by a functional block 220 labeled User Labels, Fine-Tune, Prompt-Tune Foundation Models at a line from the user-AI-interface module 216 and the foundation models 202. For example, system 200 enables bolstering foundation models 202 via retrieval augmented generation (RAG) by relating pre-application prior user modifications or constraints to new or previously generated datasets of chemical compounds, spectra, or similar data, and sharing such prior user modifications or constraints data in response to a natural language user selection or prompt, and/or other user-AI interactions.

System 200 enables natural language processing (NLP) and user selection of a portion, or a region for modification or replacement of a given chemical structure of interest presented at the user design interface 215, such as indicated by a functional block 222 labeled Natural Language Prompting and a functional block 224 labeled User selects region, group, or groups to Replace at a first line from the user-AI-interface module 216.

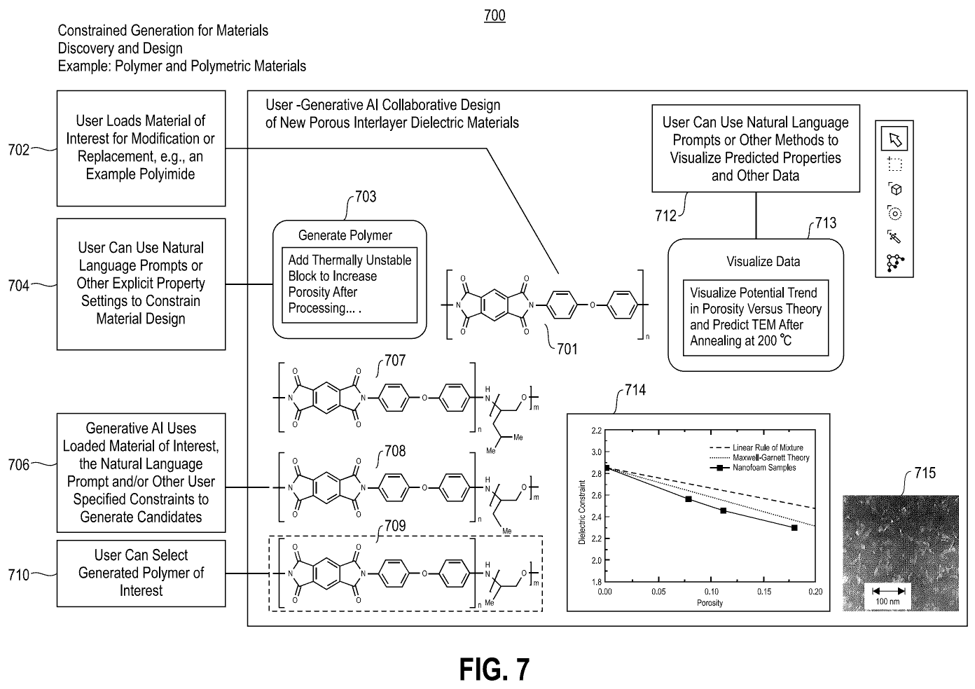

In an embodiment, system 200 implements features and operations of the user design interface 215 for improved constrained generation of materials, compounds, and design output with predicted values of interest, such as indicated by an example functional block 226 labeled Polymer Graph Representation, a functional block 228 labeled Structure with tokens to mask, and a functional block 230 labeled Regression Transformer. For example, system 200 provides at the user design interface 210, a chemical structure to be modified, such as a graphical representation or an illustrated chemical structure 701 as illustrated and described for a method 700 of FIG. 7 for generating polymer and polymeric materials. For example, in system 200 the foundation models 202 implement multitask regression transformer capabilities to reformulate or integrate regression as a conditional sequence modeling task with property-driven conditional generation for materials discovery and design. In an embodiment, system 200 can input tokens to the foundation models 202, and tuning the foundation models 202 is based on one or more of a user input selection and prompt, a generated chemical structure, and user feedback. In an embodiment, system 200 enables leveraging multi-modal foundation models 202 to assist in generating real-time, progressive visualizations of nearby chemical/material/property latent space based on user defined constraints, selections, and interaction data, such as indicated at Further Simulations 232.

System 200 performs enhanced methods of the present disclosure, which are enabled by features and operations of the foundation models 202 of disclosed embodiments. In accordance with disclosed embodiments, the foundation models 202 are large AI generative deep learning models that are trained using fine-tuning, prompt-tuning, and machine learning algorithms to implement enhanced constrained generation for new material discovery and material design. The foundation models 202 of disclosed embodiments perform in context learning, simulation, and computational chemistry processing techniques providing enhanced material discover and design output generation for the user, utilizing multiple different data modalities such as chemical structures, spectra, images, and/or natural language. The foundation models 202 can include large language model (LLM) capabilities for enhanced interactive processing of natural language tasks of user-input prompts, selections, user interactions, and feedback of disclosed embodiments. In an embodiment, system 200, by the foundation models 202, outputs a generated structure having a user-selected portion or substructure of a chemical structure replaced by a portion predicted to have a desired property indicated by a user-input prompt of a replacement portion.

In an embodiment, the foundation models 202 are trained or pre-trained on massive amounts of chemical data including the historical dataset 208, synthetic dataset 210, and pre-generated dataset 212 of the chemical database 206. In an embodiment, the foundation models 202 receive one or more of user-input interaction data, user selection data, or user-input constraint data to generate a prompt based on in-context learning and/or to perform fine-tuning of the foundation model based on of the one or more of user-input interaction data, user selection data, or user-input constraint data. In an embodiment, the foundation models 202 perform computational chemistry processing and/or simulation processing based on one or more of user-input selections, or user-input constraints (e.g., for additional analysis of generated compounds) to generate one or more modified chemical structures with predicted values of interest for the generated compounds. In an embodiment, the foundation models 202 are multimodal foundation models that combine vision and language modalities or capabilities to process and generate both textual, visual, spectrum, and structural information of materials, compounds of interest based on user-input selections, user-input prompts, user-input interactions and user-input constraints, generated chemical structures, and user feedback based on generated chemical structures. In an embodiment, system 200 processes, by the foundation models 202, spectra or characterization data and/or a dataset of materials or compounds for user-AI interaction to implement enhanced constrained generation for new material discovery and material design.

For example, historical datasets 208 includes materials or compounds with a set of properties that is processed by the foundation models 202. Synthetic datasets 208 includes synthetic data or information that is created using algorithms or artificially generated rather than produced by real-world events, and used to validate and train the foundation models 202. The pre-generated dataset 212 includes one or more datasets of outputs of generated chemical structures the foundation models 202 of prior user modifications or user-input constraints based on user-input prompts, selections, and feedback of disclosed embodiments.

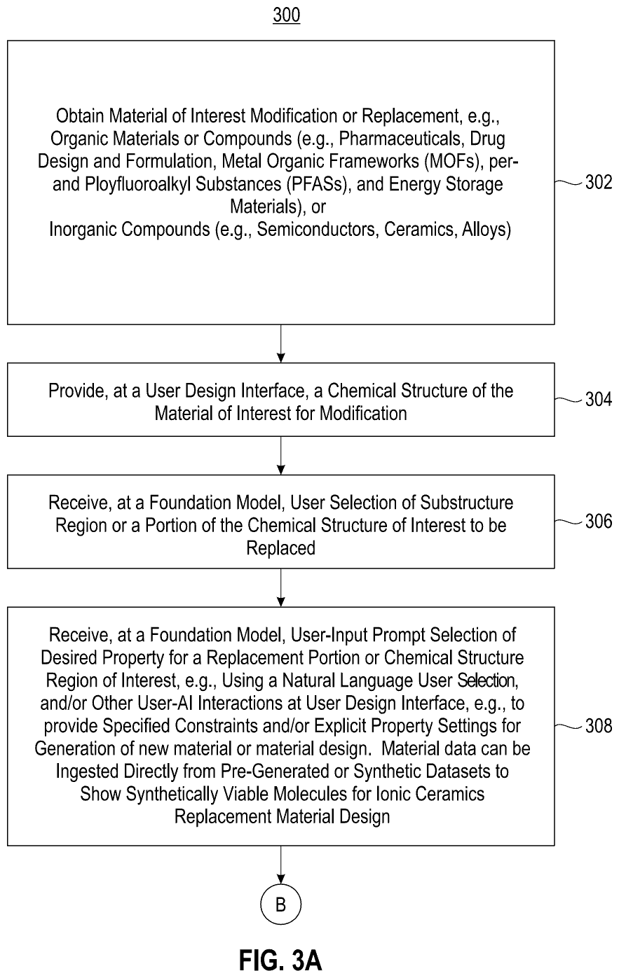

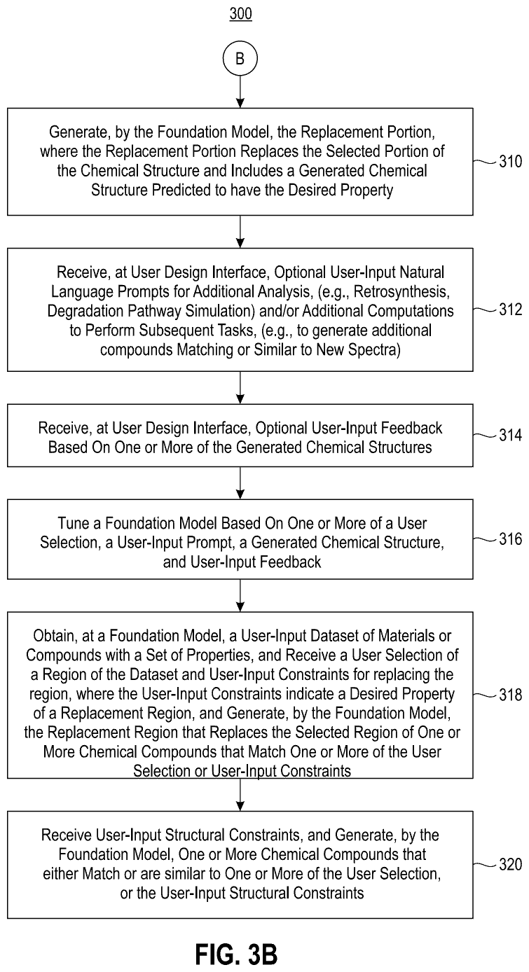

FIGS. 3A, 3B together illustrate example operations of a method 300 for implementing constrained generation for material discovery and design of one or more embodiments of the present disclosure. Method 300 can be implemented by system 200 in conjunction with the computer 101 of FIG. 1 and the Constrained Generation Control Code 182 of disclosed embodiments.

In FIGS. 3A, 3B, and 4-12, the same reference numbers are used to refer to identical or similar components of system 200 as used in FIG. 2.

At block 302, system 200, (e.g., implemented using foundation models 202) obtains a material of interest for modification or replacement in accordance with a disclosed embodiment. For example, the material of interest of disclosed embodiments may include an organic material or organic compound, (e.g., pharmaceuticals, drug-like molecules, Metal-organic frameworks (MOFs) organic polymers, perfluoroalkyl and polyfluoroalkyl substances (PFASs), and energy storage materials). The material of interest of disclosed embodiments may include an inorganic compound, (e.g., semiconductors, ceramics, or alloys). For example, the material of interest is loaded by a foundation model 202 from the database 206 of datasets 206, 208, or 210 of chemical compounds, spectra, and chemical design data including historical data, synthetic data, and pre-generated data, which includes historical user modifications, user selection data, and constraints of disclosed embodiments.

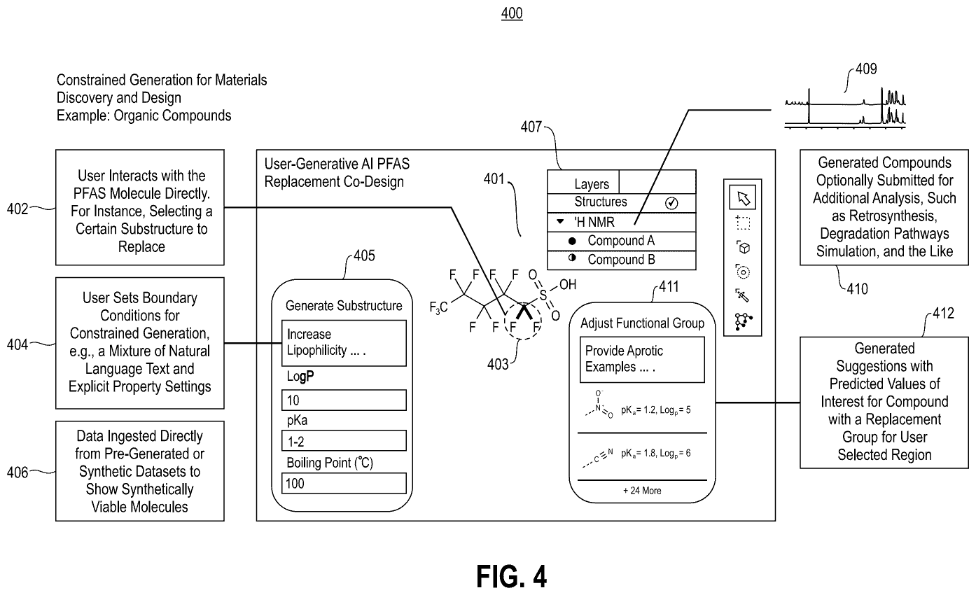

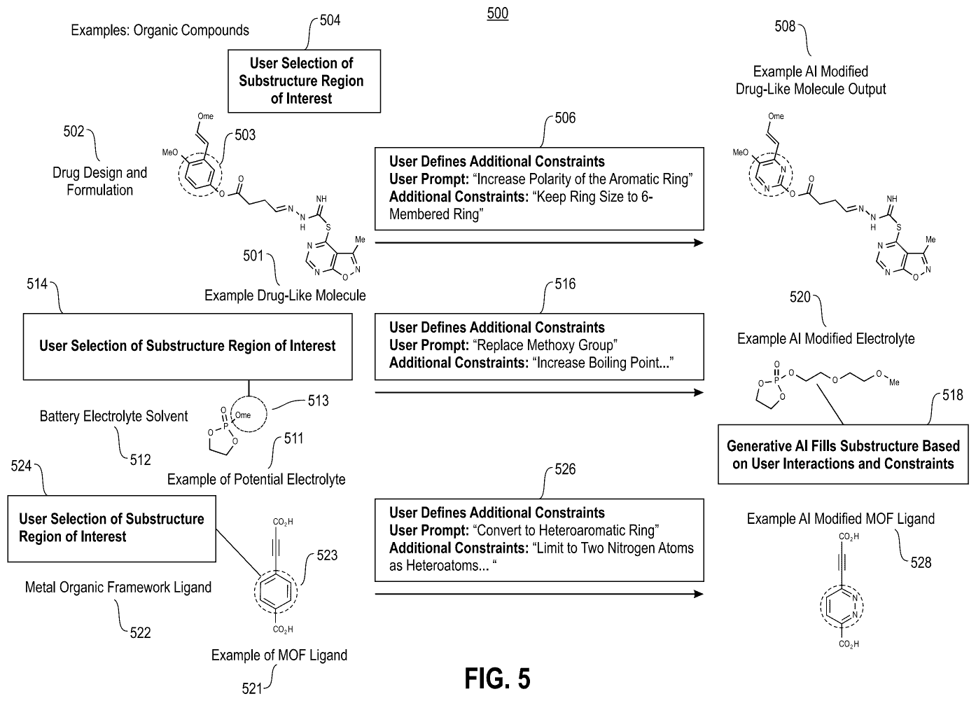

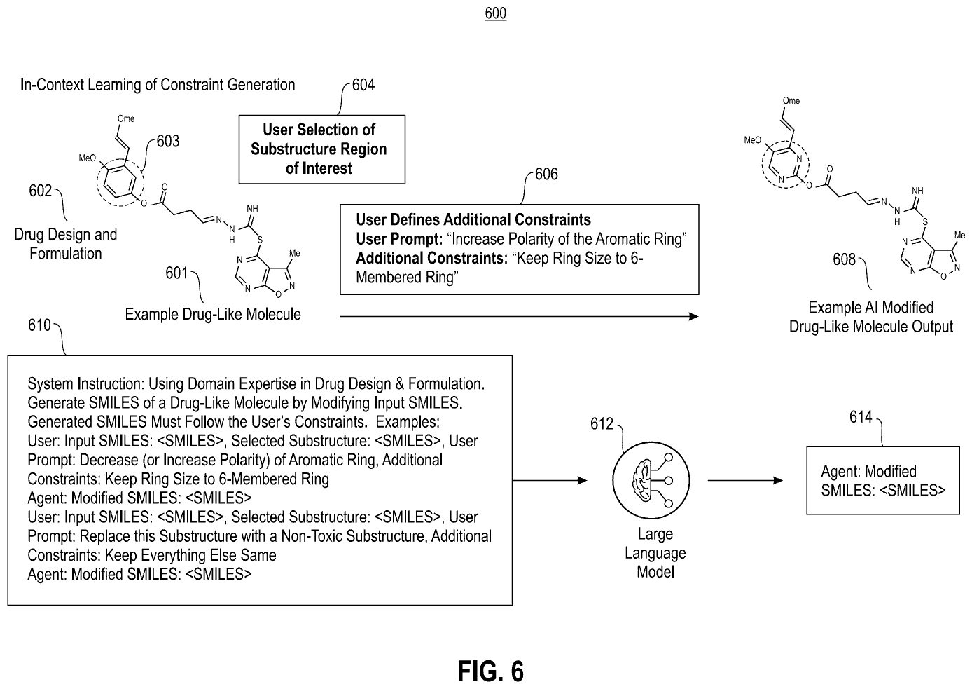

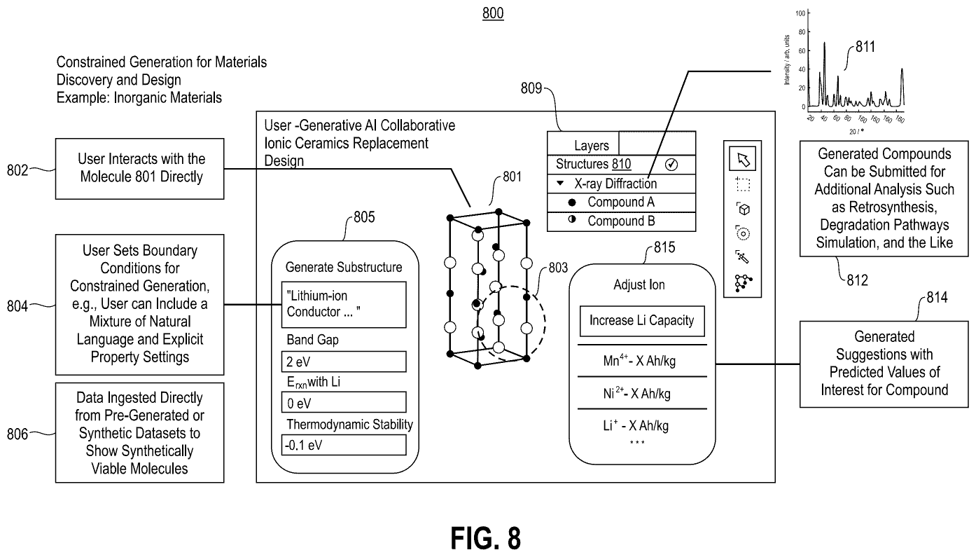

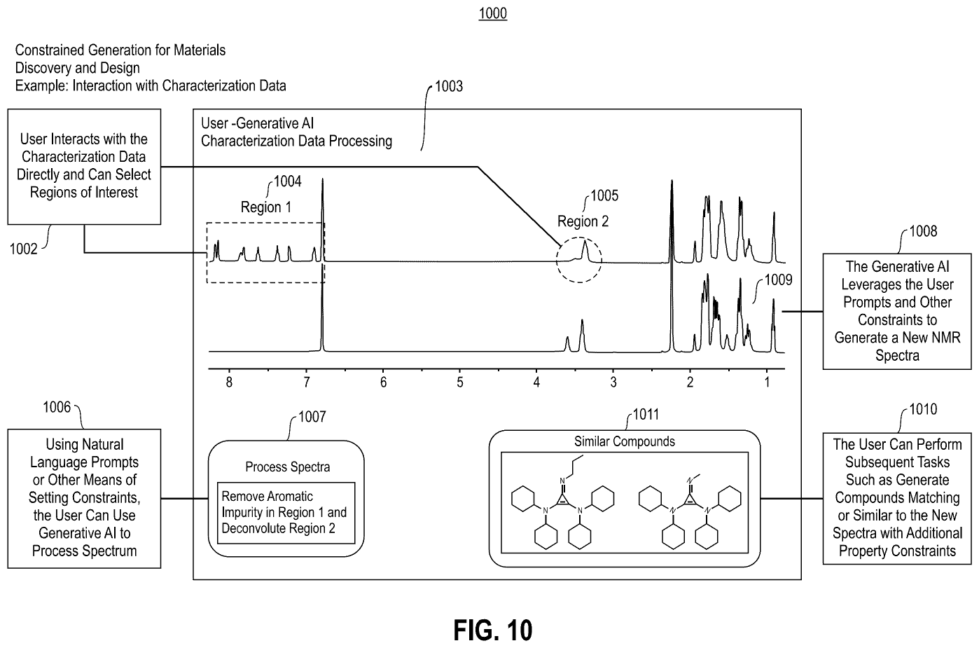

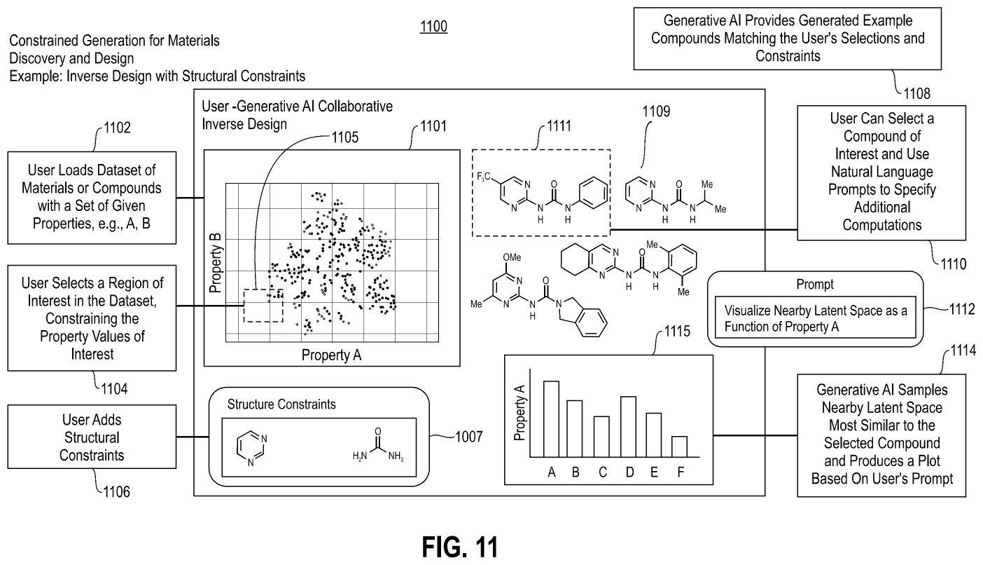

At block 304, system 200 provides, at the user design interface 215, a chemical structure of the material of interest to a user or SME. For example, a chemical molecule or compound is displayed at the user design interface 215, such as an illustrated example PFAS molecule 401 shown in FIG. 4, a drug-like molecule 501, a potential electrolyte 511, or a MOF ligand 521 shown in FIG. 5, a drug-like molecule 601 shown in FIG. 6, a polyimide 701 shown in FIG. 7, a ceramic molecule 801 shown in FIG. 8. Further, system 200 may display for the material of interest at the user design interface 215, spectra or characterization data 1001 as illustrated in FIG. 10, or a dataset 1101 of materials or compounds as shown in FIG. 11.

At block 306, system 200 receives at the foundation models 202, a user selection of a portion, or a region, of the chemical structure of interest for modification or replacement, provided by the user selection provided at the user design interface 215. For example, substructures, portions, or regions of interest are illustrated at a region 403 of PFAS molecule 401 in FIG. 4, a menu 503 (e.g., add block) of the drug-like molecule 501, a region 513 of the potential electrolyte 511, a region 523 of the MOF ligand 521 in FIG. 5, a region 603 of the drug-like molecule 601 in FIG. 6, a region 703 of the polyimide 701 in FIG. 7, a region 803 of the ceramic molecule 801 in FIG. 8. In FIG. 10, user selections of a region 1, 1004, and a region 2, 1005 of the characterization data 1001 are shown, and a user selection of a region 1105 of the dataset 1101 of materials or compounds is illustrated in FIG. 11.

At block 308, system 200 receives by the foundation models 202, a user-input prompt selection of a desired property for a replacement chemical structure portion or region of interest, for example, using a natural language user selection, and/or other user-AI interactions at the user design interface 215. For example, the user-input prompt selection can provide specified constraints, and/or explicit property settings to constrain material design or generation of a new material or formulation. In an embodiment, the material data can be ingested directly from pre-generated dataset 212 or synthetic dataset 210, for example, to show synthetically viable molecules for ionic ceramics replacement material design. Operations continue following entry point B at block 310 in FIG. 3B.

In FIG. 3B, at block 310 system 200 generates, by one or more of the foundation models 202, the replacement portion, where the replacement portion replaces the selected portion of the chemical structure of interest and includes a generated chemical structure predicted to have the desired property. For example, the generative AI foundation models 202 uses an example loaded material (at block 302 in FIG. 3A), natural language prompts, and/or specified properties and constraints to generate a set of one or more candidate materials having the replacement portion and includes a generated chemical structure predicted to have the desired property.

At block 312, system 200 receives, at a user design interface 215, one or more optional user-input natural language prompts to submit generated compounds for additional analysis, (e.g., retrosynthesis, degradation pathway simulation, or the like) and/or additional computations to perform subsequent tasks, (e.g., to generate additional compounds matching or similar to new spectra). At block 314, system 200 receives, at a user design interface 215, user-input feedback based on one or more of the generated chemical structures. For example, system 200 enables user feedback from the user or SME, such as enabling the user to input user labels based on respective generated chemical structures, user-input prompt data, user selection and constraint data, and user-AI-interaction data.

At block 316, system 200 tunes one or more of the foundation models 202 based on one or more of a user selection, a user-input prompt, a generated chemical structure, and user-input feedback. In an embodiment, system 200 can fine-tune, or prompt-tune, the generative AI foundations models 202 based at least in part on the user-input feedback to provide improved candidate generation of materials, compounds, and design output with predicted values of interest. At block 318, system 200 obtains a user-input dataset of materials or compounds with a set of properties, and receives a user-input selection of a region of the dataset and user-input constraints for replacing the region, where one or more of the user-input constraints indicate a desired property of a replacement region, and system 200 generates, by the foundation model, the replacement region that replaces the selected region of one or more chemical compounds that match one or more of the user selection or the user-input constraints. At block 320, system 200 receives user-input structural constraints; and system 200 generates, by the foundation model 202, one or more chemical compounds that either match or are similar to one or more of the user selection, or user-input structural constraints.

FIG. 4 illustrates example operations, design interface features, and results of a method 400 for constrained generation of an organic compound for materials discovery and design one or more disclosed embodiments. Method 400 can be implemented by system 200 in conjunction with the computer 101 of FIG. 1 and the Constrained Generation Control Code 182. PFAS are a group of synthetic organofluorine chemical compounds that have multiple fluorine atoms attached to an alkyl chain. System 200 provides an illustrated PFAS molecule 401 that is the material of interest at the user display interface 215. At block 402, a user interacts with the PFAS molecule 401 directly, for instance, selecting a certain substructure 403 to replace, as shown by the dotted circle within the PFAS molecule 401. At block 404, the user sets boundary conditions for constrained generation, e.g., a mixture of natural language text and explicit property settings, such as shown at display menu 405 to generate substructure including example illustrated input to ‘Increase lipophilicity’ (i.e., increase the ability of the chemical compound to dissolve in fats, oils, lipids, and non-polar solvents such as hexane or toluene) and multiple illustrated property settings, such as user-input specific property settings of log P, pKa, and Boiling Point (° C.).

As shown at block 406, system 200 can ingest data directly from pre-generated datasets 212 or synthetic datasets 210 to show synthetically viable molecules. A display menu 407 at the user display interface 215 includes user-selection options of Layers, Strictures, H NMR (e.g., example displayed spectrum example 409), Compound A, and Compound B. As shown at block 410, system 200 enables generated compounds to be optionally submitted for additional analysis, such as retrosynthesis, degradation pathways simulation, and the like. A display menu 411 at the user display interface 215 includes user selected ‘Adjust Functional Group’ and a display of example generated candidates of replacements for the substructure 403, as shown. As shown at block 412, system 200 enables display of the generated suggestions with predicted values of interest for the generated compound with the replacement portion for the substructure 403, as shown.

FIG. 5 illustrates a method 500 of constrained generation for organic compounds for materials discovery and design of one or more disclosed embodiments. Method 500 includes additional example operations, design interface features, and results for examples Drug Design and Formulation 502, Battery Electrolyte Solvent 512, and Metal Organic Framework Ligand 522.

As shown at block 504, for the Drug Design and Formulation 502, system 200 receives a user selection of a substructure region 503 of the example Drug-Like Molecule 501, that includes a user-selected aromatic 6-membered ring structure. At block 506, system 200 receives user-input additional constraints for the substructure region 503, as shown that includes a user prompt “Increase polarity of the aromatic ring” and Additional constraints: “Keep ring size to 6-membered ring.” System 200 presents at the user display interface 215, a new generated drug-like molecule of an illustrated Example AI Modified Drug-Like Molecule Output 508 that matches the drug-like molecule 501 with a generated replacement portion for the substructure 503 that includes a 6-membered aromatic ring with two Nitrogen atoms, as shown encircled in dotted line.

As shown at block 514, for the Battery Electrolyte Solvent 512, system 200 receives a user selection of a substructure region 513 of an example Potential Electrolyte 511, that includes a user-selected methoxy group OMe. At block 516, system 200 receives user-input additional constraints for replacement of the substructure region 513, as shown that includes a User prompt: “Replace methoxy group” and Additional constraints: “Increase boiling point,” and the like. At shown at block 518, system 200, using generative AI of the foundation models 202, fills the substructure portion 513 based on the user Interactions and Constraints, presents a new generated electrolyte as an illustrated Example AI Modified Electrolyte 520, with a generated replacement portion for the substructure 513 with an illustrated example reactive nonmetal chain and keeping physical properties of OMe substructure region 513 of the first compound electrolyte 511, as shown.

As shown at block 524, for the Metal Organic Framework Ligand 522, system 200 receives a user selection of a substructure region 523 of an example MOF Ligand 521, that includes a user-selected 6-membered ring. At block 526, system 200 receives user-input additional constraints for replacement of the substructure region 523, as shown that includes a User prompt: “Convert to heteroaromatic ring” and Additional constraints: “Limit to two nitrogen atoms as heteroatoms”, and the like. System 200 presents at the user display interface 215, a new generated chemical structure of an illustrated Example AI Modified MOF Ligand 528, with a generated replacement portion for the user-selected 6-membered ring substructure 523, which includes a 6-membered heteroaromatic ring with two Nitrogen atoms, as shown encircled in dotted line.

FIG. 6 illustrates example operations, design interface features, and results of an in-context learning method 600 for constraint generation used with Simplified Molecular Input Line Entry System (SMILES) strings for drug design and formulation of one or more disclosed embodiments.

Method 600 can receive instructions and operations used with a Simplified Molecular Input Line Entry System (SMILES) and uses received SMILES notation, (e.g., as shown at block 610) for example used to translate a two-dimensional chemical structure or a three-dimensional chemical structure into a string of symbols for implementing operations of the Constrained Generation Control Code 182 by computer software of disclosed embodiments.

For example, a SMILES line notation system can be used for describing a chemical structure, such as an example drug-type molecule 601 including chemical species using short ASCII strings.

In an embodiment of method 600, system 200 presents a chemical structure, such as the illustrated Example Drug-Type Molecule 601 for Drug Design and Formulation 602, (e.g., provided at user design interface 215 using foundation models 202). As shown at block 604, system 200 receives a user selection of a substructure region 603, shown encircled in dotted line (e.g. user-selected aromatic 6-membered ring structure) of the example Drug-Like Molecule 601. At block 606, system 200 receives user-input additional constraints for the substructure region 603, as shown that include a user prompt “Increase polarity of the aromatic ring” and Additional constraints: “Keep ring size to 6-membered ring.” System 200 presents at the user display interface 215, a new generated drug-like molecule such as illustrated Example AI Modified Drug-Like Molecule Output 608 that matches the drug-like molecule 601 with a generated replacement portion for the substructure 603 that includes a 6-membered aromatic ring with two Nitrogen atoms, shown encircled in dotted line in the example generated output of foundation models 202.

Method 600 can receive instructions and operations for use with Simplified Molecular Input Line Entry System (SMILES) and can use received SMILES notation or a SMILES string of symbols, for example to translate between a two-dimensional chemical structure or a three-dimensional chemical structure and SMILES strings. For example, a SMILES molecular representation or SMILES strings can be used for describing a chemical structure, such as the example drug-type molecule 601 including short ASCII strings. In an embodiment, SMILES strings are used by system 200 for implementing operations of the Constrained Generation Control Code 182 of disclosed embodiments.

At block 610, system 200 receives user-selections and constraints of system SMILES instructions (e.g., such as shown at blocks 604 and 606) for Drug Design and Formulation 602, provided in defined SMILES strings format. At block 610, multiple different examples of SMILES instructions are shown (e.g., such as shown also at blocks 504 and 506 in FIG. 5). In an embodiment, the foundation models 202 receive one or more of user-input interaction data, user selection data, or user-input constraint data to generate a prompt based on in-context learning of the one or more of user-input interaction data, user selection data, or user-input constraint data. In an embodiment, the foundation models 202 generate a chemical structure predicted to have the desired property based on the generated prompt. As illustrated at block 612, system 200 using LLM capabilities of the foundation models 202 generates output SMILES of a drug-like molecule by modifying input SMILES, and the generated output SMILES follow the user-input selections and constraints (e.g., as shown at block 610). At block 614, system 200 transmits the generated output SMILES, for example of the drug-like molecule 601, with an agent of any suitable implementation for use with the database 206 and optionally other external databases of chemical molecules or chemical compounds represented by Agent: Modified SMILES: <SMILES>.

FIG. 7 illustrates example operations, design interface features, and results of a method 700 of constrained generation of example polymer and polymeric materials (e.g., porous interlayer dielectric materials) for materials discovery and design of disclosed embodiments. Method 700 can be implemented by system 200 in conjunction with the computer 101 of FIG. 1 and the Constrained Generation Control Code 182.

As shown at block 702, a user loads a material of interest for modification or replacement, such as, the example polyimide 701, received by the foundation models 202. As illustrated, system 200 displays a menu Generate Polymer 703 with user-input “Add thermally unstable block to increase porosity after processing.”

At block 704, system 200 obtains user-selections and constraints, the user can use natural language prompts or other explicit property settings to constrain material design. At block 706, system 200 using the foundation models 202, generative AI uses loaded material 701 of interest, the natural language prompt and/or other user specified constraints at menu block 703 to generate polymer candidates, such as illustrated example generated structures 707, 708, and 709.

At block 710, system 200 obtains user-selection of a generated material, or polymer of interest, such as illustrated example generated polymer structure 709 shown in dotted line of the example generated polymer structure output by foundation models 202.

At block 712, system 200 obtains user-selection to visualize predicted properties and other data of the selected generated structure 709, output by foundation models 202. For example, the user can use natural language prompts or other methods to visualize predicted properties and other data of the selected generated structure 709. In an embodiment, system 200 receives, at a user design interface 215, user-input natural language prompts for additional analysis and computations to perform subsequent tasks. As illustrated, system 200 displays a menu Visualize Data 713 with user-input “Visualize potential trend in porosity versus theory and predict TEM after annealing at 200° C.” of the selected generated structure 709. For example in an embodiment, system 200 displays an example chart 714 to illustrate example user-selected functions of dielectric constant versus porosity, and an example transmission electron microscopy (TEM) image 715, for the selected generated structure 709.

FIG. 8 illustrates example operations, design interface features, and results of a constrained generation method 800 of an example inorganic material (e.g., ionic ceramics replacement) for materials discovery and design of disclosed embodiments. Method 800 can be implemented by system 200 in conjunction with the computer 101 of FIG. 1 and the Constrained Generation Control Code 182. As illustrated, system 200 provides (e.g., using foundation models 202) at the user design interface 215, an inorganic material of interest for modification or replacement, such as an illustrated ceramic molecule 801. At block 802, system 200 receives at the foundation models 202, a user selection of a portion 803 (i.e., substructure) of the ceramic molecule 801 for modification or replacement, provided at the user design interface 215 by the user directly interacting the ceramic molecule 801.

At block 804, system 200, receives user selections to set boundary conditions for the constrained generation, e.g., user can include a mixture of natural language and explicit property settings. As illustrated, system 200 displays a menu Generate Substructure 805 with user-inputs “Lithium-ion conductor”, and the like, and other user-input selections, Bandgap, Eᵣₓₙ with Li, and Thermodynamic Stability, as shown.

At block 806, system 200 ingests data directly from pre-generated or synthetic datasets to show synthetically viable molecules by the foundation models 202, for example, to show one or more synthetically viable ceramic molecule based on the user-input selections of the region 803 of the ceramic molecule 801 and the user-input constraints at block 804. As illustrated, system 200 displays a menu 809 including selected Structures 810 with user-inputs X-ray Diffraction, Compound A or Compound B. For example in an embodiment, system 200 displays an example chart 811 showing Intensity versus elastic scattering of X-rays from the selected structure 810.

At block 812, system 200 receives, at the user design interface 215, optional user-input natural language prompts to submit generated compounds for additional analysis, and for example one or more generated compounds can be submitted for additional analysis such as retrosynthesis, degradation pathways simulation, and the like. At block 814, system 200 presents, at the user design interface 215, generated suggestions with predicted values of interest for compound. As illustrated in an embodiment, system 200 displays a menu Adjust Ion 815 with user-input “Increase Lithium capacity”, and displays candidate generated electron configurations with predicted values including Mn⁴⁺-X Ah/kg, Ni²⁺-X Ah/kg, and Li⁺-X Ah/k, as shown.

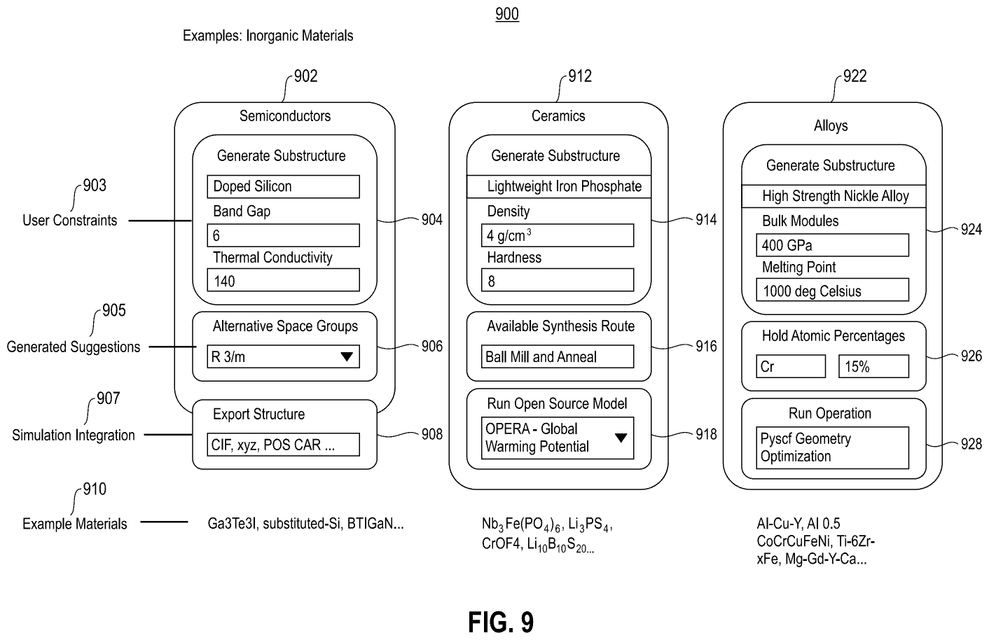

FIG. 9 illustrates example operations, design interface features, and results of a constrained generation method 900 for example inorganic materials for materials discovery and design of one or more disclosed embodiments. Method 900 can be implemented by system 200 in conjunction with the computer 101 of FIG. 1 and the Constrained Generation Control Code 182.

In FIG. 9, example inorganic materials for materials discovery and design of disclosed embodiments include Semiconductors 902, Ceramics 912, and Alloys 922. For each of the Semiconductors 902, Ceramics 912, and Alloys 922, there are shown User Constraints 903 to generate a substructure, Generated Suggestions 905 of example constraints, Simulation Integration 907 of example structure or operations, and Example Materials 910 generated by method 900.

In an embodiment for Semiconductors 902, as illustrated in an embodiment, system 200 displays a menu Generate Substrate 904 with a user-input selection of Doped Silicon, and user-input selections of Band gap and Thermal conductivity for the User Constraints 903. In an embodiment, system 200 displays a menu Alternative Space Groups 906 of R3/m for the Generated Suggestions 905 of example constraints, and Export Structure 908 for the Simulation Integration 907 of example structure or operations, and displays example generated semiconductor materials for the Example Materials 910 output by the foundation models 202, including, such as, Ga3Te3I, substituted-Si, BTlGaN, as shown.

In an embodiment for Ceramics 912, as illustrated in an embodiment, system 200 displays a menu Generate Substrate 914 with a user-input selection of Lightweight Iron phosphate, and user-input selections of Density and Hardness for the User Constraints 903. In an embodiment, system 200 displays a menu Available Synthesis Route 916 of Ball Mill and Anneal for the Generated Suggestions 905 of example constraints. In an embodiment, system 200 displays a menu Run Open Source Model 918 of OPERA (Open (Quantitative) Structure-activity/property Relationship App)—Global Warming Potential for the Simulation Integration 907 for Ceramics 912. As shown, in an embodiment, system 200 displays example generated ceramic materials for the Example Materials 910 output by the foundation models 202, such as including Nb₃Fe(PO₄)₆, Li₃PS₄, CrOF₄, Li₁₀B₁₀S₂₀, as shown.

For Alloys 922, in an illustrated embodiment, system 200 displays a menu Generate Substrate 914 with a user-input selection of High strength Nickel Alloy, and user-input selections of Bulk Modulus and Melting Point for the User Constraints 903, as shown. In an embodiment, system 200 displays a menu Hold atomic percentages 926 of Cr and 15% for the Generated Suggestions 905 of example constraints and Run Operation 928 of PySCF (Python-based simulations of chemistry framework) geometry optimization (e.g. PySCF used for quantum chemical simulations) for the Simulation Integration 907, and system 200 displays example generated alloy materials for the Example Materials 910 output by the foundation models 202, such as including Al—Cu—Y, Al 0.5 CoCrCuFeNi, Ti-6Zr-xFe, Mg—Gd—Y—Ca, as shown.

FIG. 10 illustrates chemical structure example operations, design interface features, and results of a constrained generation method 1000 including example interaction with characterization data processing for materials discovery and design of one or more disclosed embodiments. Method 1000 can be implemented by system 200 in conjunction with the computer 101 of FIG. 1 and the Constrained Generation Control Code 182.

At block 1002, system 200, (e.g., implemented using foundation models 202) loads characterization data 1003 of a material of interest for modification or replacement in accordance with disclosed embodiments. As shown at block 1002, the user interacts with the characterization data 1003 directly and can select regions of interest, such as Region 1, 1004 and Region 2, 1005, as shown encircled in dotted lines. At block 1006, system 200 enables user-inputs of natural language prompts or other user-input selections to set constraints, to use generative AI (e.g., implemented using foundation models 202) to process the spectrum of characterization data 1003. In an embodiment, system 200 displays a menu, such as illustrated Process Spectra 1007, to receive one or more user-inputs such as illustrated “Remove aromatic impurity in region 1 and de-convolute region 2.”

At block 1008, system 200 leverages generative AI of foundation models 202 based on the user-input prompts and other constraints to generate a new NMR spectrum, such as illustrated at 1009. As shown at block 1002, system 200 enables the user to perform subsequent tasks such as generate compounds matching or similar to the new spectra with additional property constraints. As illustrated, system 200 displays Similar Compounds 1011, providing respective example chemical structures of generated compounds based on the characterization data 1003 and the user-input prompts and other user-input selections setting constraints.

FIG. 11 is a diagram illustrating example operations, design interface features, and results of a constrained generation method 1100 of an example inverse design and structural constraints for materials discovery and design of disclosed embodiments. Method 1100 can be implemented by system 200 in conjunction with the computer 101 of FIG. 1 and the Constrained Generation Control Code 182.

At block 1102, system 200 (e.g., implemented using foundation models 202) loads a dataset 1101 of materials or compounds with a set of given properties, for example Property A, and Property B, as illustrated. At block 1104, system 200, enables the user to select a region of interest in the dataset, such as a region 1105 as shown in dotted line, and constraining the property values of interest. At block 1106, system 200, enables the user to add structural constraints, such as illustrated Structural Constraints 1107. At block 1108, system 200 uses generative AI of foundation models 202 based on the user-input prompts and other constraints to generate example compounds matching the user's selections and constraints, such as example illustrated generated chemical structures 1109, output by one or more of the foundation models 202.

At block 1110, system 200 enables the user to select a compound of interest and use natural language prompts to specify additional computations, such as the selected compound 1111 as shown in dotted line. As illustrated, system 200 receives a user-input Prompt 1112, for example, to “Visualize nearby latent space as a function of property A.”

At block 1114, system 200 using generative AI of foundation models 202, samples nearby latent space most similar to the selected compound 1111 and to produce a plot based on the user-input prompt 1112, such as Chart 1115 for Property A with user-selected relative latent space values represented by functions A, B, C, D, E, F.

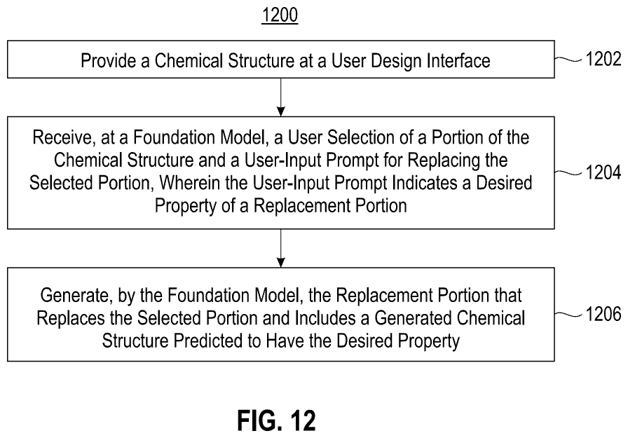

FIG. 12 illustrates example features and operations of a method 1200 for implementing constrained generation for materials discovery and design of one or more disclosed embodiments. Method 400 can be implemented by system 200 in conjunction with the computer 101 of FIG. 1 and the Constrained Generation Control Code 182.

At block 1202, system 200 provides a chemical structure at a user design interface. In an embodiment, system 200 provides the chemical structure of interest to a user or SME at the user design interface 215, such as described with respect to block 304 of FIG. 3A, and the illustrated examples described above (e.g., the PFAS molecule 401 shown in FIG. 4, the drug-like molecule 501 shown in FIGS. 5 and 6, the potential electrolyte 511, or the MOF ligand 521), or spectra or characterization data 1001 as illustrated in FIG. 10, or a dataset 1101 of materials or compounds as shown in FIG. 11.

At block 1204, system 200 receives, at a foundation model, a user selection of a portion of the chemical structure and a user-input prompt for replacing the portion, where the user-input prompt indicates a desired property of a replacement portion. In an embodiment, system 200 receives user-input at the user design interface 215, such as described with respect to blocks 306 and 308 of FIG. 3A, and the illustrated example substructures, portions, or regions of interest illustrated in FIGS. 4-8, 10, and 11.

At block 1204, system 200 generates, by the foundation model, the replacement portion that replaces the selected portion of the chemical structure and includes a generated chemical structure predicted to have the desired property. In an embodiment, system 200 generates one or more generated chemical structures having the replacement portion that replaces the selected portion and includes the generated chemical structure predicted to have the desired property, for example, as described with respect to block 310 of FIG. 3B, and the illustrated example replacement substructures of the generated chemical structures predicted to have the desired property illustrated in FIGS. 4-8, 10, and 11.

While the foregoing is directed to embodiments of the present invention, other and further embodiments of the invention may be devised without departing from the basic scope thereof, and the scope thereof is determined by the claims that follow.

What is claimed is:

1. A method comprising:
providing, using one or more processors, a chemical structure at a design interface;
receiving, at a foundation model, a user selection of a portion of the chemical structure and a user-input prompt for replacing the portion, wherein the user-input prompt indicates a desired property of a replacement portion; and
generating, by the foundation model, the replacement portion, wherein the replacement portion replaces the selected portion of the chemical structure and includes a generated chemical structure predicted to have the desired property.

2. The method of claim 1, further comprising:
receiving, at the foundation model, user-input interactions and user-input constraints for modifying the replacement portion; and
generating, by the foundation model, a modified chemical structure for the replacement portion based on one or more of the user-input interactions, and the user-input constraints.

3. The method of claim 1, wherein the user-input prompt comprises at least one of natural language prompts, boundary conditions, a combination of natural language and explicit property settings.

4. The method of claim 1, wherein the user-input prompt comprises user-input property settings that indicate the desired property of the replacement portion, wherein the user-input property settings comprise one or more of a physical property, a chemical property, a thermal property, and a mechanical property.

5. The method of claim 1, further comprising:
obtaining a user-input dataset of materials or compounds with a set of properties; and
receiving, at a foundation model, a user selection of a region of the dataset and one or more user-input constraints for replacing the region, wherein the one or more user-input constraints indicate a desired property of a replacement region.

6. The method of claim 5, further comprising:
receiving user-input structural constraints; and
generating, by the foundation model, the replacement region that replaces the selected region of one or more materials or compounds that match one or more of the user selection, the one or more user-input constraints, and the user-input structural constraints.

7. The method of claim 1, further comprising:
tracking and encoding at least one of user selections, user-input interactions, and user-input constraints for ingestion into the foundation model for constrained generation of a modified chemical structure.

8. The method of claim 1, further comprising:
generating visualizations of chemical, material, or property latent space of the generated chemical structure based on one or more of user defined constraints, selections, and interaction data.

9. The method of claim 1, further comprising:
receiving, at the foundation model, one or more of user-input interaction data, user selection data, and user-input constraint data to generate a prompt based on in-context learning of the one or more of user-input interaction data, user selection data, and user-input constraint data.

10. The method of claim 1, further comprising:
receiving, at the foundation model, one or more of user-input interaction data, user selection data, and user-input constraint data; and
performing fine-tuning of the foundation model based on the one or more of user-interaction data, user selection data, and user-input constraint data.

11. The method of claim 1, further comprising:
performing, by the foundation model, one or more of computational chemistry processing and simulation processing based on one or more of user-input selections, and user-input constraints to generate a modified chemical structure.

12. A method comprising:
providing, using one or more processors, a chemical structure at a design interface;
receiving, at a foundation model, a user selection of a portion of the chemical structure and a user-input prompt for replacing the portion, wherein the user-input prompt indicates a desired property of a replacement portion;
generating, by the foundation model, the replacement portion, wherein the replacement portion replaces the selected portion of the chemical structure and includes a generated chemical structure predicted to have the desired property receiving user feedback based on the generated chemical structure; and
tuning the foundation model based on one or more of the user selection, the user-input prompt, the generated chemical structure, and the user feedback.

13. A method comprising:
providing, using one or more processors, a chemical structure at a design interface;
receiving, at a foundation model, a user selection of a portion of the chemical structure and a user-input prompt for replacing the portion, wherein the user-input prompt indicates a desired property of a replacement portion;
generating, by the foundation model, the replacement portion, wherein the replacement portion replaces the selected portion of the chemical structure and includes a generated chemical structure predicted to have the desired property; and
wherein receiving, at the foundation model, further comprises receiving, by retrieval augmented generation (RAG) of the foundation model, historical data of one or more of prior user modifications or user-input constraints to one or more pre-generated datasets of chemical compounds, spectra, or similar data, and
sharing the historical data in response to a natural language user selection or user interaction.

14. A system, comprising:
one or more computer processors; and
a memory containing a program which when executed by the one or more computer processors performs an operation, the operation comprising:
providing, using one or more processors, a chemical structure at a design interface;
receiving, at a foundation model, a user selection of a portion of the chemical structure and a user-input prompt for replacing the portion, wherein the user-input prompt indicates a desired property of a replacement portion; and
generating, by the foundation model, the replacement portion, wherein the replacement portion replaces the selected portion of the chemical structure and includes a generated chemical structure predicted to have the desired property.

15. The system of claim 14, further comprising:
receiving, at the foundation model, user-input interactions and user-input constraints for modifying the replacement portion; and
generating, by the foundation model, a modified chemical structure for the replacement portion based on one or more of the user-input interactions, and the user-input constraints.

16. The system of claim 14, further comprising:
receiving user feedback based on the generated chemical structure; and
tuning the foundation model based on one or more of the user input selection, the user-input prompt, the generated chemical structure, and the user feedback.

17. The system of claim 14, wherein the user-input prompt comprises at least one of natural language prompts, boundary conditions, and a combination of natural language and explicit property settings.

18. The system of claim 14, wherein the user-input prompt comprises user-input property settings that indicate the desired property of the replacement portion, wherein the user-input property settings comprise one or more of a physical property, a chemical property, a thermal property, and a mechanical property.

19. The system of claim 14, further comprising;
receiving, at the foundation model, one or more of user-input interaction data, user selection data, or user-input constraint data to generate a prompt based on in-context learning of the one or more of user-input interaction data, user selection data, and user-input constraint data.

20. A computer program product for materials discovery and design, the computer program product comprising a computer-readable storage medium having computer-readable program code embodied therewith, the computer-readable program code executable by one or more computer processors to perform an operation comprising:
providing, using one or more processors, a chemical structure at a design interface;
receiving, at a foundation model, a user selection of a portion of the chemical structure and a user-input prompt for replacing the portion, wherein the user-input prompt indicates a desired property of a replacement portion; and
generating, by the foundation model, the replacement portion, wherein the replacement portion replaces the selected portion of the chemical structure and includes a generated chemical structure predicted to have the desired property.

21. The computer program product of claim 20, further comprising:
receiving, at the foundation model, user-input interactions and user-input constraints for modifying the replacement portion; and
generating, by the foundation model, a modified chemical structure for the replacement portion based on one or more of the user-input interactions, and user-input constraints.

22. The computer program product of claim 20, further comprising:
receiving user feedback based on the generated chemical structure; and
tuning the foundation model based on one or more of the user input selection, the user-input prompt, the generated chemical structure, and the user feedback.

23. The computer program product of claim 20, wherein the user-input prompt comprises at least one of natural language prompts, boundary conditions, and a combination of natural language and explicit property settings.

24. The computer program product of claim 20, wherein the user-input prompt comprises user-input property settings that indicates the desired property of the replacement portion, wherein the user-input property settings comprise one or more of a physical property, a chemical property, a thermal property, and a mechanical property.
